(19) United States
(12) Patent Application Publication
(10) Pub. No.: US 2026/0142272 A1
(43) Pub. Date: May 21, 2026

(54) PORTABLE ENERGY SYSTEM

(71) Applicant: Enphase Energy, Inc., Fremont, CA (US)

(72) Inventors: Ajay CHIDAMBARAM SWARNALATHA, Kanyakumari District (IN); John Sunil Kumar PALLE, Whitefield (IN); Vikas BANSAL, Bangalore (IN); Sophie Adrienne WHITEHEAD, Austin, TX (US)

(21) Appl. No.: 19/378,595

(22) Filed: Nov. 4, 2025

(30) Foreign Application Priority Data
Nov. 21, 2024 (IN) 202411090574

(51) Int. Cl. H01M 10/6563; H01M 10/613; H01M 10/63; H01M 10/643; H01M 50/213; H02J 7/00; H05K 7/20

(52) U.S. Cl. CPC H01M 10/6563; H01M 10/613; H01M 10/63; H01M 10/643; H01M 50/213; H02J 7/50; H02J 7/855; H05K 7/20909

(57) ABSTRACT

A portable energy system is provided and comprises a front panel comprising a first vent, a rear panel comprising a second vent, and a battery module comprising a plurality of battery cells spaced apart from each other to allow airflow between the plurality of battery cells from the first vent to the second vent during charging and discharging of the battery module such that the plurality of battery cells are maintained within a specified temperature of the battery module.

### CROSS-REFERENCE TO RELATED APPLICATIONS

The present application claims the benefit of and priority to Indian Provisional Application Serial No. 202411090574, filed on Nov. 21, 2024, the entire contents of which is incorporated herein by reference.

### BACKGROUND

### 1. Field of the Disclosure

Embodiments of the present disclosure generally relate to portable energy systems, and for example, to portable energy systems with improved thermal management configurations.

### 2. Description of the Related Art

Conventional portable energy systems configured for use with energy management systems are known. Portable energy systems, however, can have one or more challenges in thermal performance management. For example, when portable energy systems have front to back airflow and comprise one or more LED displays and/or output and input connectors, a power conditioner unit (PCU) and a battery pack temperature must be maintained within acceptable limits under continuous operation. For example, for a given form factor, the battery back may need to be maintained within 55° C. under continuous operation (e.g., about 1 C (C-rate) charging and 1.2 C discharging). Additionally, to satisfy weight constraints for PCUs with relatively high power densities (e.g., 500 W), the PCUs must be thermally managed within the given form factor and low acoustic impact.

In view of the foregoing, the inventors provide herein portable energy systems with improved thermal management configurations.

### SUMMARY

In accordance with some aspects of the present disclosure, there is provided a portable energy comprising a front panel comprising a first vent, a rear panel comprising a second vent, and a battery module comprising a plurality of battery cells spaced apart from each other to allow airflow between the plurality of battery cells from the first vent to the second vent during charging and discharging of the battery module such that the plurality of battery cells are maintained within a specified temperature of the battery module.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only a typical embodiment of this disclosure and are therefore not to be considered limiting of its scope, for the disclosure may admit to other equally effective embodiments.

FIG. 1 is a block diagram of a system for power conversion, in accordance with at least some embodiments of the present disclosure;

FIG. 2 is a block diagram of an AC battery system configured for use with the system of FIG. 1, in accordance with at least some embodiments of the present disclosure;

FIGS. 3A-3D are various views of a portable energy system for power conversion configured for use with the system of FIG. 1, in accordance with at least some embodiments of the present disclosure;

FIG. 3E is the enlarged area of detail of FIG. 3D, in accordance with at least some embodiments of the present disclosure;

FIG. 4 is a cutaway view showing an airflow direction within the portable energy system, in accordance with at least some embodiments of the present disclosure; and

FIG. 5 is a partial back view showing fan placement within the portable energy system, in accordance with at least some embodiments of the present disclosure.

### DETAILED DESCRIPTION

As noted above, portable energy systems with improved thermal management configurations are disclosed herein. For example, a portable energy system can comprise a front panel comprising a first vent, a rear panel comprising a second vent, and a battery module comprising a plurality of battery cells spaced apart from each other to allow airflow between the plurality of battery cells from the first vent to the second vent during charging and discharging of the battery module such that the plurality of battery cells are maintained within a specified temperature of the battery module. When compared to conventional portable energy systems, the portable energy systems described herein provide improved thermal management configurations.

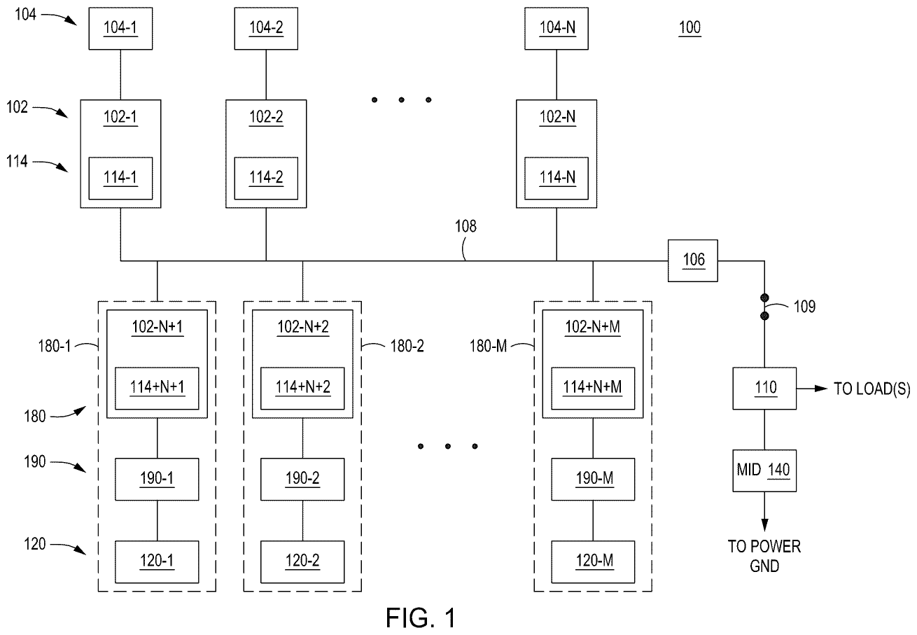

FIG. 1 is a block diagram of a system 100 (energy management system) for power conversion using one or more embodiments of the present disclosure. This diagram only portrays one variation of the myriad of possible system configurations and devices that may utilize the present disclosure.

The system 100 is a microgrid that can operate in both an islanded state and in a grid-connected state (i.e., when connected to another power grid (such as one or more other microgrids and/or a commercial power grid). The system 100 can comprise one or more power converters. In at least some embodiments, the system 100 comprises a plurality of power converters 102-1, 102-2, . . . 102-N, 102-N+1, and 102-N+M collectively referred to as power converters 102 (which also may be called power conditioners); a plurality of DC power sources 104-1, 104-2, . . . 104-N, collectively referred to as power sources 104; a plurality of energy storage devices/delivery devices 120-1, 120-2, . . . 120-M collectively referred to as energy storage/delivery devices 120; a system controller 106; a plurality of BMUs 190-1, 190-2, . . . 190-M (battery management units) collectively referred to as BMUs 190; a system controller 106; a bus 108; a load center 110; and a MID 140 (microgrid interconnect device (or an island interconnect device IID)) or a relay disconnect or similar). In some embodiments, such as the embodiments described herein, the energy storage/delivery devices are rechargeable batteries (e.g., multi-C-rate collection of AC batteries, of various types of Lithium-ion based chemistries or similar) which may be referred to as batteries 120, although in other embodiments the energy storage/delivery devices may be any other suitable device for storing energy and providing the stored energy. Generally, each of the batteries 120 comprises a plurality cells that are coupled in series and/or parallel, e.g., eight cells coupled in series and six cells coupled in parallel to each series cell to form a battery 120.

Each power converter 102-1, 102-2 . . . 102-N is coupled to a DC power source 104-1, 104-2 . . . 104-N, respectively, in a one-to-one correspondence, although in some other embodiments multiple DC power sources may be coupled to one or more of the power converters 102 that converts DC to DC power. The power converters 102-N+1, 102-N+2 . . . 102-N+M are respectively coupled to plurality of energy storage devices/delivery devices 120-1, 120-2 . . . 120-M via BMUs 190-1, 190-2 . . . 190-M to form AC batteries 180-1, 180-2 . . . 180-M, respectively. Each of the power converters 102-1, 102-2 . . . 102-N+M comprises a corresponding controller 114-1, 114-2 . . . 114-N+M (collectively referred to as the inverter controllers 114) for controlling operation of the power converters 102-1, 102-2 . . . 102-N+M.

In some embodiments, such as the embodiment described below, the DC power sources 104 are DC power sources and the power converters 102 are bidirectional inverters such that the power converters 102-1 . . . 102-N convert DC power from the DC power sources 104 to grid-compliant AC power that is coupled to the bus 108, and the power converters 102-N+1 . . . 102-N+M convert (during energy storage device discharge) DC power from the batteries 120 to grid-compliant AC power that is coupled to the bus 108 and also convert (during energy storage device charging) AC power from the bus 108 to DC output that is stored in the batteries 120 for subsequent use. The DC power sources 104 may be any suitable DC source, such as an output from a previous power conversion stage, a battery, a renewable energy source (e.g., a solar panel or photovoltaic (PV) module, a wind turbine, a hydroelectric system, or similar renewable energy source), or the like (e.g., 12V or 24V or 48V car battery based regulated DC source), for providing DC power. In other embodiments the power converters 102 may be other types of converters (such as DC-DC converters), and the bus 108 is a DC power bus. In such embodiments, the battery can provide 60V that is sent to different DC converters to drive, for example, 5V, 9V, 12V, 15V, 20V etc., all of which can be straight DC outputs for charging one or more DC devices, e.g., mobile phones, laptops, speakers, LED lights etc. These are independent from Battery powering the Power converters for AC outputs.

The power converters 102 are coupled to the system controller 106 via the bus 108 (which also may be referred to as an AC line or a power grid, AC generator (propane, LGP, or similar, AC from windfarms, etc.). The system controller 106 generally comprises a CPU coupled to each of support circuits and a memory that comprises a system control module for controlling some operational aspects of the system 100 and/or monitoring the system 100 (e.g., issuing certain command and control instructions to one or more of the power converters 102, collecting data related to the performance of the power converters 102, and the like). The system controller 106 is capable of communicating with the power converters 102 (e.g., DC/AC power converters, DC/DC power converters, which can be housed in the same enclosure or in separate enclosures) by wireless and/or wired communication (e.g., power line communication) for providing certain operative control and/or monitoring of the power converters 102.

In some embodiments, the system controller 106 may be a gateway that receives data (e.g., performance data) from the power converters 102 and communicates (e.g., via the Internet) the data and/or other information to a remote device or system, such as a master controller (not shown). Additionally or alternatively, the gateway may receive information from a remote device or system (not shown) and may communicate the information to the power converters 102 and/or use the information to generate control commands that are issued to the power converters 102.

The power converters 102, which, as noted above, can be AC/DC power converters or DC/DC power converters) are coupled to the load center 110 via the bus 108, and the load center 110 is coupled to the power grid via the MID 140. When coupled to the power grid (e.g., a commercial grid or a larger microgrid) via the MID 140, the system 100 may be referred to as grid-connected; when disconnected from the power grid via the MID 140, the system 100 may be referred to as islanded or microgrid or off grid or similar nomenclature. The MID 140 determines when to disconnect from/connect to the power grid (e.g., the MID 140 may detect a grid fluctuation, disturbance, outage or the like) and performs the disconnection/connection. Once disconnected from the power grid, the system 100 can continue to generate power as an intentional island, without imposing safety risks on any line workers that may be working on the power grid, using the droop control techniques described herein. The MID 140 comprises a disconnect component (e.g., a disconnect relay(s)) for physically disconnecting/connecting the system 100 from/to the power grid. In some embodiments, the MID 140 may additionally comprise an autoformer for coupling the system 100 to a split-phase load that may have a misbalance in it with some neutral current (examples include US grid system like 120V/240V split single-phase systems). In certain embodiments, the system controller 106 comprises the MID 140 or a portion of the MID 140.

The power converters 102 convert the DC power from the DC power sources 104 and discharging batteries 120 to grid-compliant AC power and couple the generated output power to the load center 110 via the bus 108. The power is then distributed to one or more loads (for example to one or more appliances) and/or to the power grid (when connected to the power grid). Additionally or alternatively, the generated energy may be stored for later use, for example using batteries, heated water, hydro pumping, H₂O-to-hydrogen conversion, or the like. Generally, the system 100 is coupled to the commercial power grid, although in some embodiments the system 100 is completely separate from the commercial power grid and operates as an independent microgrid.

In some embodiments, the AC power generated by the power converters 102 is single-phase AC power. In other embodiments, the power converters 102 generate three-phase AC power.

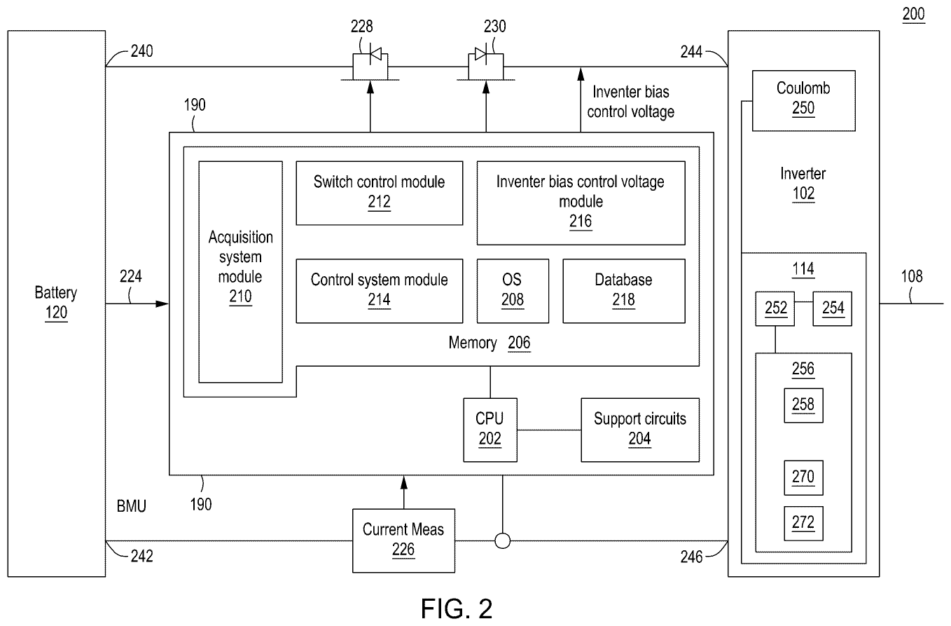

A storage system configured for use with an energy management system, such as the ENSEMBLE® energy management system available from ENPHASE®, is described herein. For example, FIG. 2 is a block diagram of an AC battery system 200 (e.g., a storage system) in accordance with one or more embodiments of the present disclosure. Alternatively, the AC battery system 200 can be a DC battery system with a corresponding battery and DC/DC power converters.

The AC battery system 200 comprises a BMU 190 coupled to a battery 120 and a power converter 102. A pair of metal-oxide-semiconductor field-effect transistors (MOSFETs) or BJT or IGBT or similar switches—switches 228 and 230—are coupled in series between a first terminal 240 of the battery 120 and a first terminal of the inverter 144 such the body diode cathode terminal of the switch 228 is coupled to the first terminal 240 of the battery 120 and the body diode cathode terminal of the switch 230 is coupled to the first terminal 244 of the power converter 102. The gate terminals of the switches 228 and 230 are coupled to the BMU 190, these switches are configured for controlling the charging to or discharging from the battery.

A second terminal 242 of the battery 120 is coupled to a second terminal 246 of the power converter 102 via a current measurement module 226 which measures the current flowing between the battery 120 and the power converter 102.

The BMU 190 is coupled to the current measurement module 226 for receiving information on the measured current, and also receives an input 224 from the battery 120 indicating the battery cell voltage and temperature. The BMU 190 is coupled to the gate terminals of each of the switches 228 and 230 for driving the switch 228 to control battery discharge and driving the switch 230 to control battery charge as described herein. The BMU 190 is also coupled across the first terminal 244 and the second terminal 246 for providing an inverter bias control voltage (which may also be referred to as a bias control voltage) to the inverter 102 as described further below.

The configuration of the body diodes of the switches 228 and 230 allows current to be blocked in one direction but not the other depending on state of each of the switches 228 and 230. When the switch 228 is active (i.e., on) while the switch 230 is inactive (i.e., off), battery discharge is enabled to allow current to flow from the battery 120 to the power converter 102 through the body diode of the switch 230. When the switch 228 is inactive while the switch 230 is active, battery charge is enabled to allow current flow from the power converter 102 to the battery 120 through the body diode of the switch 228. When both switches 228 and 230 are active, the system is in a normal mode where the battery 120 can be charged or discharged.

The BMU 190 comprises support circuits 204 and a memory 206 (e.g., non-transitory computer readable storage medium), each coupled to a CPU 202 (central processing unit). The CPU 202 may comprise one or more processors, microprocessors, microcontrollers and combinations thereof configured to execute non-transient software instructions to perform various tasks in accordance with embodiments of the present disclosure. The CPU 202 may additionally or alternatively include one or more application specific integrated circuits (ASICs). In some embodiments, the CPU 202 may be a microcontroller comprising internal memory for storing controller firmware that, when executed, provides the controller functionality described herein. The BMU 190 may be implemented using a general purpose computer that, when executing particular software, becomes a specific purpose computer for performing various embodiments of the present disclosure.

The support circuits 204 are well known circuits used to promote functionality of the CPU 202. Such circuits include, but are not limited to, a cache, power supplies, clock circuits, buses, input/output (I/O) circuits, and the like. The BMU 190 may be implemented using a general-purpose computer that, when executing particular software, becomes a specific purpose computer for performing various embodiments of the present disclosure. In one or more embodiments, the CPU 202 may be a microcontroller comprising internal memory for storing controller firmware that, when executed, provides the controller functionality described herein.

The memory 206 may comprise random access memory, read only memory, removable disk memory, flash memory, and various combinations of these types of memory. The memory 206 is sometimes referred to as main memory and may, in part, be used as cache memory or buffer memory. The memory 206 generally stores the OS 208 (operating system), if necessary, of the inverter controller 114 that can be supported by the CPU capabilities. In some embodiments, the OS 208 may be one of a number of commercially available operating systems such as, but not limited to, LINUX, Real-Time Operating System (RTOS), and the like.

The memory 206 stores non-transient processor-executable instructions and/or data that may be executed by and/or used by the CPU 202 to perform, for example, one or more methods for discharge protection, as described in greater detail below. These processor-executable instructions may comprise firmware, software, and the like, or some combination thereof. The memory 206 stores various forms of application software, such as an acquisition system module 210, a switch control module 212, a control system module 214, and an inverter bias control module 216. The memory 206 additionally stores a database 218 for storing data related to the operation of the BMU 190 and/or the present disclosure, such as one or more thresholds, equations, formulas, curves, and/or algorithms for the control techniques described herein. In various embodiments, one or more of the acquisition system module 210, the switch control module 212, the control system module 214, the inverter bias control module 216, and the database 218, or portions thereof, are implemented in software, firmware, hardware, or a combination thereof.

The acquisition system module 210 obtains the cell voltage and temperature information from the battery 120 via the input 224, obtains the current measurements provided by the current measurement module 226, and provides the cell voltage, cell temperature, and measured current information to the control system module 214 for use as described herein.

The switch control module 212 drives the switches 228 and 230 as determined by the control system module 214. The control system module 214 provides various battery management functions, including protection functions (e.g., overcurrent (OC) protection, overtemperature (OT) protection, and hardware fault protection), metrology functions (e.g., averaging measured battery cell voltage and battery current over, for example, 100 ms to reject 50 and 60 Hz ripple), state of charge (SOC) analysis (e.g., coulomb gauge 250 for determining current flow and utilizing the current flow in estimating the battery SOC; synchronizing estimated SOC values to battery voltages (such as setting SOC to an upper bound, such as 100%, at maximum battery voltage; setting SOC to a lower bound, such as 0%, at a minimum battery voltage); turning off SOC if the power converter 102 never drives the battery 120 to these limits; and the like), balancing (e.g., autonomously balancing the charge across all cells of a battery to be equal, which may be done at the end of charge, at the end of discharge, or in some embodiments both at the end of charge and the end of discharge). By establishing upper and lower estimated SOC bounds based on battery end of charge and end of discharge, respectively, and tracking the current flow and cell voltage (i.e., battery voltage) between these events, the BMU 190 determines the estimated SOC.

The inverter controller 114 comprises support circuits 254 and a memory 256, each coupled to a CPU 252 (central processing unit). The CPU 252 may comprise one or more processors, microprocessors, microcontrollers and combinations thereof configured to execute non-transient software instructions to perform various tasks in accordance with embodiments of the present disclosure. The CPU 252 may additionally or alternatively include one or more application specific integrated circuits (ASICs). In some embodiments, the CPU 252 may be a microcontroller comprising internal memory for storing controller firmware that, when executed, provides the controller functionality herein. The inverter controller 114 may be implemented using a general-purpose computer that, when executing particular software, becomes a specific purpose computer for performing various embodiments of the present disclosure.

The support circuits 254 are well known circuits used to promote functionality of the CPU 252. Such circuits include, but are not limited to, a cache, power supplies, clock circuits, buses, input/output (I/O) circuits, and the like. The inverter controller 114 may be implemented using a general-purpose computer that, when executing particular software, becomes a specific purpose computer for performing various embodiments of the present disclosure. In one or more embodiments, the CPU 252 may be a microcontroller comprising internal memory for storing controller firmware that, when executed, provides the controller functionality described herein.

The memory 256 may comprise random access memory, read only memory, removable disk memory, flash memory, and various combinations of these types of memory. The memory 256 is sometimes referred to as main memory and may, in part, be used as cache memory or buffer memory. The memory 256 generally stores the OS 258 (operating system), if necessary, of the inverter controller 114 that can be supported by the CPU capabilities. In some embodiments, the OS 258 may be a number of commercially available operating systems such as, but not limited to, LINUX, Real-Time Operating System (RTOS), and the like.

The memory 256 stores non-transient processor-executable instructions and/or data that may be executed by and/or used by the CPU 252. These processor-executable instructions may comprise firmware, software, and the like, or some combination thereof. The memory 256 stores various forms of application software, such as a power conversion control module 270 for controlling the bidirectional power conversion, and a battery management control module 272.

The BMU 190 communicates with the system controller 106 to perform balancing of the batteries 120 (e.g., multi-C-rate collection of AC batteries) based on a time remaining before each of the batteries are depleted of charge, to perform droop control (semi-passive) which allows the batteries to run out of charge at substantially the same time, and perform control of the batteries to charge batteries having less time remaining before depletion using batteries having more time remaining before depletion.

As mentioned above, the portable energy systems described herein provide improved thermal management configurations. For example, in the event of thermal runaway of a cell/group of cells, the portable energy systems described herein are capable of containing a fire and heat, i.e., without leading to severe propagation. Additionally, the battery module configuration provides a proper venting path for all the battery cells of the battery module.

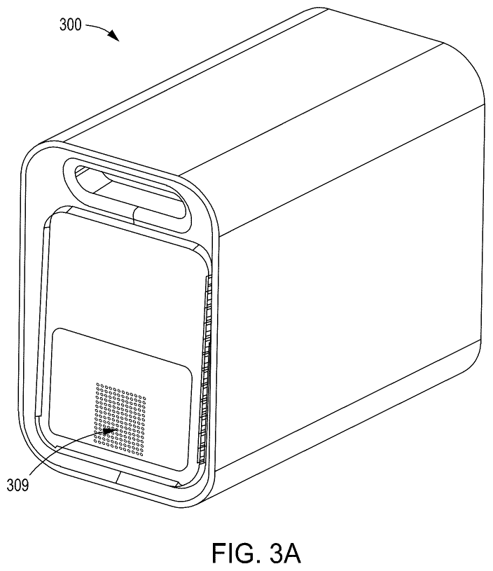

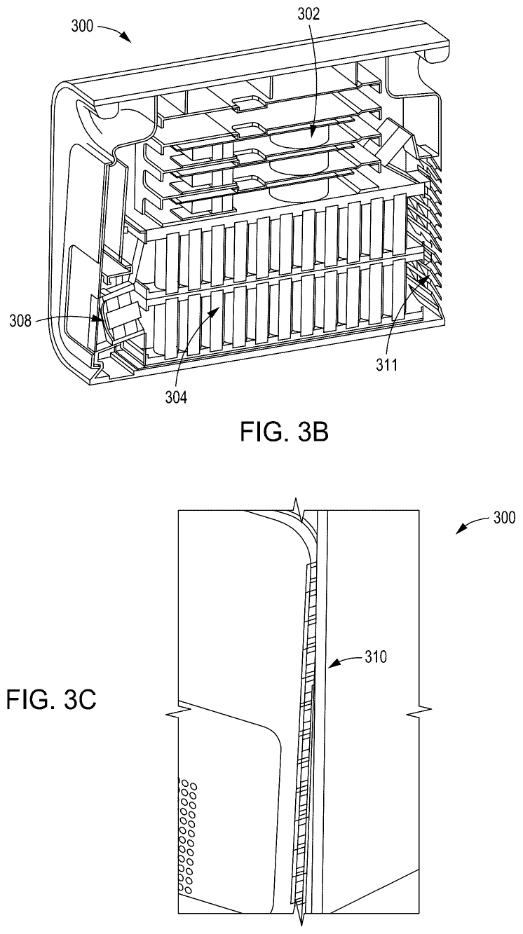

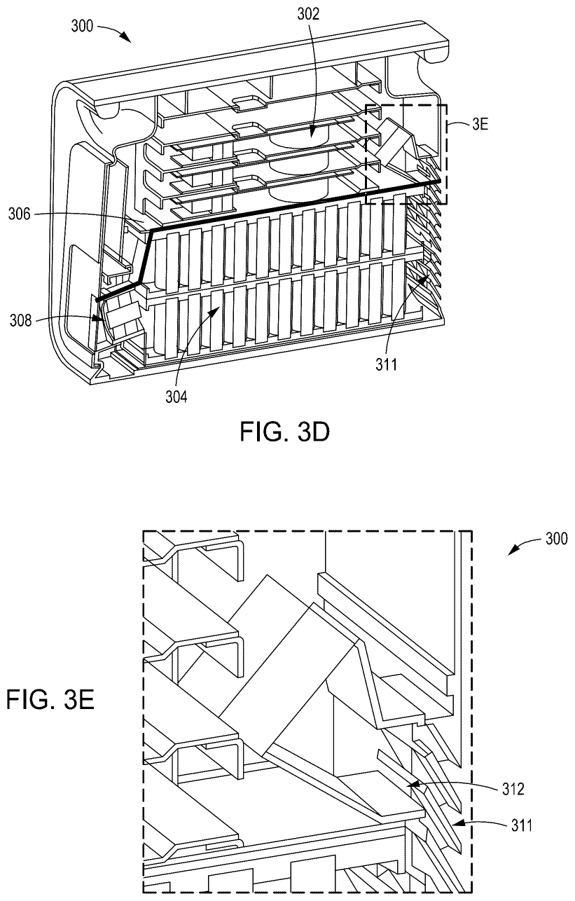

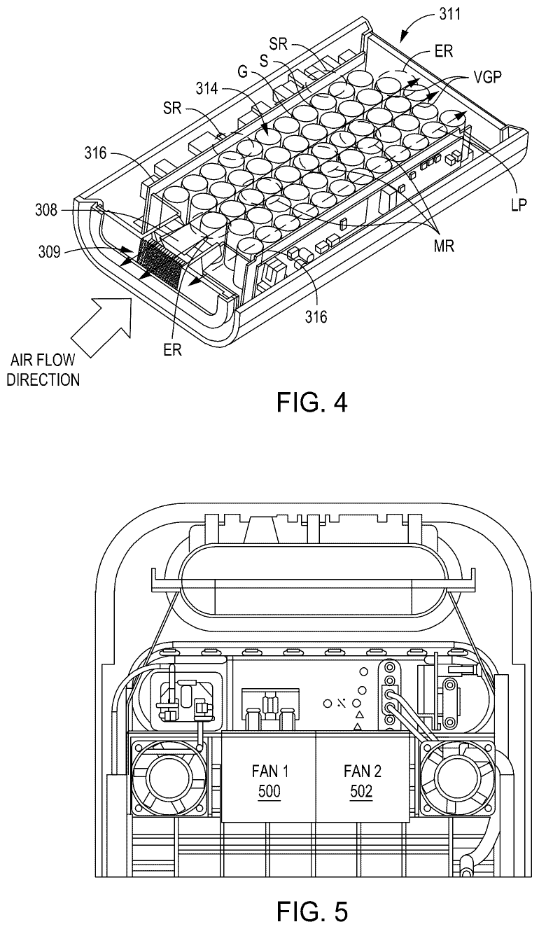

FIGS. 3A-3D are various views of a portable energy system (a PES 300) for power conversion configured, for example, for use with the system of FIG. 1, FIG. 3E is the enlarged area of detail of FIG. 3D, FIG. 4 is a cutaway view showing an airflow direction within the portable energy system, and FIG. 5 is a partial back view showing fan placement within the portable energy system, in accordance with at least some embodiments of the present disclosure.

For example, the PES 300 is configured to house one or more PCUs 302 (e.g., inverter stacks) and one or more battery packs 304 (e.g., battery modules), see FIG. 3B. The internal configuration of the PES 300 provides isolation between the one or more PCUs 302 and the one or more battery packs 304. For example, in at least some embodiments, an isolation plate 306 (see FIG. 3D) is disposed between the one or more PCUs 302 and the one or more battery packs 304 and is configured to isolate the one or more PCUs 302 from the one or more battery packs 304 (e.g., a thermal runaway), which helps to regulate a temperature for wide varying thermal limits (e.g., 50° C. to about 125° C.).

A channel 308 (see FIGS. 3B and 3D), which is behind a vent 309 (a first vent, see FIG. 3A) on a front panel of the PES 300, provides a passage for directly exposing the one or more battery packs 304 to the outside ambient to help satisfy the relatively low temperature requirements of the one or more battery packs 304 (e.g., about 50° C.). A duct 312, which is behind a vent 311 (a second vent) on a rear panel of the PES 300, is configured to pull out air through the one or more PCUs 302 (see FIGS. 3D and 3E). Additionally, unlike PESs that have one or more fans disposed at the sides of the rear panel of the PES, the PES 300 comprises one or more fans (e.g., two fans, a fan 500 and a fan 502) that are disposed at the center of the rear panel of the PES 300), see FIG. 5 for example. In at least some embodiments, the fan 500 and the fan 502 are ducted towards the center of the one or more PCUs 302 (e.g., inverter stack) for maximum performance (e.g., cooling). For example, when the PES 300 is configured to house three (3) PCUs stacked upon each other, the fan 500 and the fan 502 can provide AC FET cooling and transformer core cooling of about 7° C. to about 13° C., respectively.

In at least some embodiments, PCU inlets 310 (FIG. 3C) are disposed on the front panel of the PES 300 and configured to prevent rain/moisture from entering the inside of the PES 300. For example, the PCU inlets 310 can be relatively small openings that are configured to allow air passage, which prevents the rain and moisture from entering inside.

Continuing with reference now to FIG. 4, the configuration of the channel 308, the vent 309, the vent 311, and a battery fan (not explicitly shown) allows maximum air flow AF to be directed across/between the individual cells 314 (battery cells) of the one or more battery packs 304 such that the individual cells 314 are maintained within a specified temperature of the one or more battery packs 304. For example, in at least some embodiments, a spacing S between the individual cells 314 can be about 2.65 mm (between adjacent cells of adjacent rows of cells) and gap G of about 0.2 mm (between adjacent cells disposed in the same row) in a lateral direction has been found to satisfy the form factor of the one or more battery packs 304. Additionally, the inventors have found that for continuous charging and discharging, the fan flow rate of the battery fan can be maintained above 16 CFM at about 40° C. and 10 CFM at about 27° C. For example, a velocity of the airflow between the individual the individual cells 314 (e.g., with spacing S of 2.65 mm and a gap G of about 0.2 mm), while maintaining the fan 502 above 16 CFM at about 40° C., can be about 6 m/s for middle regions MR of the individual the individual cells 314 and about 6-7 m/s for side regions SR and end regions ER of the individual the individual cells 314.

Additionally, the spacing S between the individual cells 314 provides a vent gas path VGP for hot gases to be directed between the individual cells 314 of the one or more battery packs 304. The inventors have found that providing a reduced longitudinal pitch LP reduces the flow of gases in the lateral direction, which prevents accumulation of the gases and accelerates venting. An aluminum casing 316 is disposed at the sides (disposed at sidewalls) of the PES 300 and is configured to prevent gas flow past the aluminum casing 316 during extreme propagation (thermal runaway).

While the foregoing is directed to embodiments of the present disclosure, other and further embodiments of the disclosure may be devised without departing from the basic scope thereof, and the scope thereof is determined by the claims that follow.

1. A portable energy system, comprising:
a front panel comprising a first vent;
a rear panel comprising a second vent; and
a battery module comprising a plurality of battery cells spaced apart from each other to allow airflow between the plurality of battery cells from the first vent to the second vent during charging and discharging of the battery module such that the plurality of battery cells are maintained within a specified temperature of the battery module.

2. The portable energy system of claim 1, wherein the plurality of battery cells are spaced apart from each other at about 2.65 mm between adjacent cells of adjacent rows of cells.

3. The portable energy system of claim 1, wherein the plurality of battery cells are spaced apart from each other at about 0.2 mm between adjacent cells disposed in a same row.

4. The portable energy system of claim 1, wherein during charging and discharging of the battery module, a fan flow rate of a battery fan can be maintained above 16 CFM for maintaining the plurality of battery cells at about 40° C.

5. The portable energy system of claim 1, wherein during charging and discharging of the battery module, a fan flow rate of a battery fan can be maintained above 10 CFM for maintaining the plurality of battery cells at about 27° C.

6. The portable energy system of claim 1, wherein during charging and discharging of the battery module, a velocity of the airflow between the plurality of battery cells is about 6 m/s for middle regions of the plurality of battery cells and about 6-7 m/s for side regions and end regions of the plurality of battery cells.

7. The portable energy system of claim 1, further comprising two fans that are disposed at a center of the rear panel.

8. The portable energy system of claim 7, wherein the two fans are ducted towards a center of an inverter stack for maximum cooling.

9. The portable energy system of claim 7, wherein the two fans are configured to provide AC FET cooling and transformer core cooling of 7° C. to about 13° C., respectively.

10. The portable energy system of claim 1, further comprising an aluminum casing disposed at sidewalls of the portable energy system and configured to prevent gas flow past the aluminum casing during thermal runaway.

11. The portable energy system of claim 1, wherein the plurality of battery cells are spaced apart from each other and have a longitudinal pitch that at least one of reduces a flow of gases in a lateral direction, prevents accumulation of the gases, and accelerates venting of the gases.

12. An energy management system, comprising:
a DC power source connected to one or more loads;
a portable energy system connected to the one or more loads and comprising:
a front panel comprising a first vent;
a rear panel comprising a second vent; and
a battery module comprising a plurality of battery cells spaced apart from each other to allow airflow between the plurality of battery cells from the first vent to the second vent during charging and discharging of the battery module such that the plurality of battery cells are maintained within a specified temperature of the battery module.

13. The energy management system of claim 12, wherein the plurality of battery cells are spaced apart from each other at about 2.65 mm between adjacent cells of adjacent rows of cells.

14. The energy management system of claim 12, wherein the plurality of battery cells are spaced apart from each other at about 0.2 mm between adjacent cells disposed in a same row.

15. The energy management system of claim 12, wherein during charging and discharging of the battery module, a fan flow rate of a battery fan can be maintained above 16 CFM for maintaining the plurality of battery cells at about 40° C.

16. The energy management system of claim 12, wherein during charging and discharging of the battery module, a fan flow rate of a battery fan can be maintained above 10 CFM for maintaining the plurality of battery cells at about 27° C.

17. The energy management system of claim 12, wherein during charging and discharging of the battery module, a velocity of the airflow between the plurality of battery cells is about 6 m/s for middle regions of the plurality of battery cells and about 6-7 m/s for side regions and end regions of the plurality of battery cells.

18. The energy management system of claim 12, further comprising two fans that are disposed at a center of the rear panel.

19. The energy management system of claim 18, wherein the two fans are ducted towards a center of an inverter stack for maximum cooling.

20. The energy management system of claim 18, wherein the two fans are configured to provide AC FET cooling and transformer core cooling of 7° C. to about 13° C., respectively.
